(19) United States
(12) Patent Application Publication
(10) Pub. No.: US 2007/0228480 A1
(43) Pub. Date: Oct. 4, 2007

(54) CMOS device having PMOS and NMOS transistors with different gate structures

(75) Inventors: Fong-Yu Yen, Taoyuan (TW); Peng-Fu Hsu, Hsinchu (TW); Ying Jin, Singapore (SG)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/395,175

(22) Filed: Apr. 3, 2006

(51) Int. Cl. H01L 29/78

(52) U.S. Cl. 257/369; 257/410

(57) ABSTRACT

A CMOS device has PMOS and NMOS transistors with different gate structures overlying a semiconductor device. A first gate structure overlying the PMOS device region has a first gate dielectric layer overlying the semiconductor substrate, and a first gate conductor overlying the first gate dielectric layer. A second gate device region overlying the NMOS device region has a second gate dielectric layer overlying the semiconductor substrate, and a second gate conductor overlying the first gate dielectric layer. The first gate conductor has a silicon-based material layer, and the second gate conductor has a metal-based material layer.

### TECHNICAL FIELD

The present invention relates to complementary metal oxide semiconductor (CMOS) integrated circuits, and particularly to p-channel metal oxide semiconductor (PMOS) and n-channel metal oxide semiconductor (NMOS) transistors having different gate structures.

### BACKGROUND

Complementary metal oxide semiconductor (CMOS) technology typically formed by establishing both n-channel metal oxide semiconductor (NMOS) transistor and p-channel metal oxide semiconductor (PMOS) transistor within a semiconductor substrate, is very widely used in current integrated circuit manufacture. In a conventional CMOS device for both NMOS and PMOS transistors, gate dielectrics are typically formed of silicon dioxide, while gate conductors are formed of polysilicon that may have opposite doping types. That is, gate structures for both the NMOS and PMOS transistors have the same material and thickness of the gate dielectric and the gate conductor. However, polysilicon used as a gate conductor material is problematic for CMOS scaling, including poly depletion, high gate resistance and boron penetration into the channel region. Also, as continuous scaling down of device dimensions, the use of thinner silicon dioxide for the gate dielectric is necessary, causing gate leakage concern. In order to solve the above-mentioned problems, a gate structure of high-k dielectric/metal stack becomes an imperative technology, especially beyond the 45 nm technologies.

The use of high-k dielectrics allows a thicker gate dielectric layer to be used for supplying capacitances equal to a thinner silicon dioxide layer, or has an effective oxide thickness (EOT) equal to the thinner silicon dioxide layer, thus offering reduced leakage. The use of metal gates provides advantages such as no boron penetration from polysilicon gate into channel through very thin gate dielectric, much lower gate resistance, and reduced electrical thickness of gate dielectric. The most significant advantage is derived through elimination of depletion in heavily doped polysilicon gates.

However, high-k dielectric/metal gate technology suffers from challenges to suitable materials for optimizing gate structures of the CMOS device. One challenge is that it is difficult to find metal gates with suitable band-edge states for NMOS and PMOS transistors, especially for PMOS transistors. The other challenge is that the metal gates need tunable work functions for NMOS and PMOS transistors respectively, for instance requiring the work functions of metal gates to range from about 4.1 eV to about 4.4 eV for NMOS and from about 4.8 eV to about 5.2 eV for PMOS. The work function of metal gates also shows strong dependence on composition of high-k dielectrics due to the so-called Fermi-level pinning or existence of other extrinsic states. In addition, effective oxide thickness of the NMOS transistor might be different from that of the PMOS transistor (e.g., the difference is typically greater than 2 Angstroms for different metal gates on the same high-k dielectric thickness) due to interaction of the metal gate and the gate dielectric or metal deposition technologies. More severe leakage is observed in NMOS transistors. It is extremely hard to find out suitable metal gates for NMOS transistor and PMOS transistor on the same gate dielectric.

### SUMMARY OF THE INVENTION

Embodiments of the present invention include a CMOS integrated circuit having an NMOS transistor and a PMOS transistor with different gate structures.

In one aspect, the present invention provides a semiconductor device includes a semiconductor substrate having a p-channel metal oxide semiconductor (PMOS) device region and an n-channel metal oxide semiconductor (NMOS) device region. A first gate structure overlying the PMOS device region has a first gate dielectric layer overlying the semiconductor substrate, and a first gate conductor overlying the first gate dielectric layer. A second gate device region overlying the NMOS device region has a second gate dielectric layer overlying the semiconductor substrate, and a second gate conductor overlying the first gate dielectric layer. The first gate conductor comprises a silicon-based material layer, and the second gate conductor comprises a metal-based material layer.

In another aspect, the present invention provides a semiconductor device includes a semiconductor substrate having a p-channel metal oxide semiconductor (PMOS) device region and an n-channel metal oxide semiconductor (NMOS) device region. A first gate structure overlying the PMOS device region has a first gate dielectric layer overlying the semiconductor substrate, and a first gate conductor overlying the first gate dielectric layer. A second gate device region overlying the NMOS device region has a second gate dielectric layer overlying the semiconductor substrate, and a second gate conductor overlying the first gate dielectric layer. The first gate conductor comprises a metal-based material layer, and the second gate conductor comprises a silicon-based material layer.

In another aspect, the present invention provides a semiconductor device includes a semiconductor substrate having a p-channel metal oxide semiconductor (PMOS) device region and an n-channel metal oxide semiconductor (NMOS) device region. A first gate structure overlying the PMOS device region has a first gate dielectric layer formed of SiON overlying the semiconductor substrate, and a first gate conductor formed of polysilicon overlying the first gate dielectric layer. A second gate device region overlying the NMOS device region has a second gate dielectric layer formed of a high-k dielectric material overlying the semiconductor substrate, and a second gate conductor formed of a metal-based material overlying the first gate dielectric layer.

### BRIEF DESCRIPTION OF THE DRAWINGS

The aforementioned objects, features and advantages of this invention will become apparent by referring to the following detailed description of the preferred embodiments with reference to the accompanying drawings, wherein:

FIG. 1A to FIG. 1F are cross-sectional diagrams illustrating an exemplary embodiment of a method of forming different gate structures for a PMOS transistor and an NMOS transistor.

FIG. 2A to FIG. 2B are cross-sectional diagrams illustrating an exemplary embodiment of a method of forming gate structures without using the capping layer;

FIG. 3A to FIG. 3D are cross-sectional diagrams illustrating an exemplary embodiment of a method of forming gate structures without using the protection layer; and

FIG. 4A to FIG. 4B are cross-sectional diagrams illustrating an exemplary embodiment of a method of forming gate structures without using the protection layer and the capping layer.

### DETAILED DESCRIPTION OF ILLUSTRATIVE EMBODIMENTS

Embodiments of the present invention provide a CMOS integrated circuit having an NMOS transistor and a PMOS transistor with different gate structures. According to the present invention, the PMOS transistor has a first gate conductor and a first gate dielectric with first dielectric properties (dielectric material and/or dielectric constant) and a first dielectric thickness which optimize the performance and reliability of the PMOS transistor, while the NMOS transistor has a second gate conductor and a second gate dielectric with second dielectric properties (dielectric material and/or dielectric constant) and a second dielectric thickness which optimize the performance and reliability of the NMOS transistor. As to the conductive materials used to form the gate electrodes, the first gate conductor is different than the second gate conductor. As to the dielectric materials used to form the gate dielectrics, the first dielectric material is different than the second dielectric material, and/or the first dielectric thickness is different than the second dielectric thickness. By utilizing different gate structures for the PMOS transistor and the NMOS transistor, electrical performance and reliability of both types of transistors are maximized and optimized which in turn improves the resulting CMOS integrated circuit.

Reference will now be made in detail to the present embodiments, examples of which are illustrated in the accompanying drawings. Wherever possible, the same reference numbers are used in the drawings and the description to refer to the same or like parts. In the drawings, the shape and thickness of one embodiment may be exaggerated for clarity and convenience. This description will be directed in particular to elements forming part of, or cooperating more directly with, apparatus in accordance with the present invention. It is to be understood that elements not specifically shown or described may take various forms well known to those skilled in the art. Further, when a layer is referred to as being on another layer or “on” a substrate, it may be directly on the other layer or on the substrate, or intervening layers may also be present.

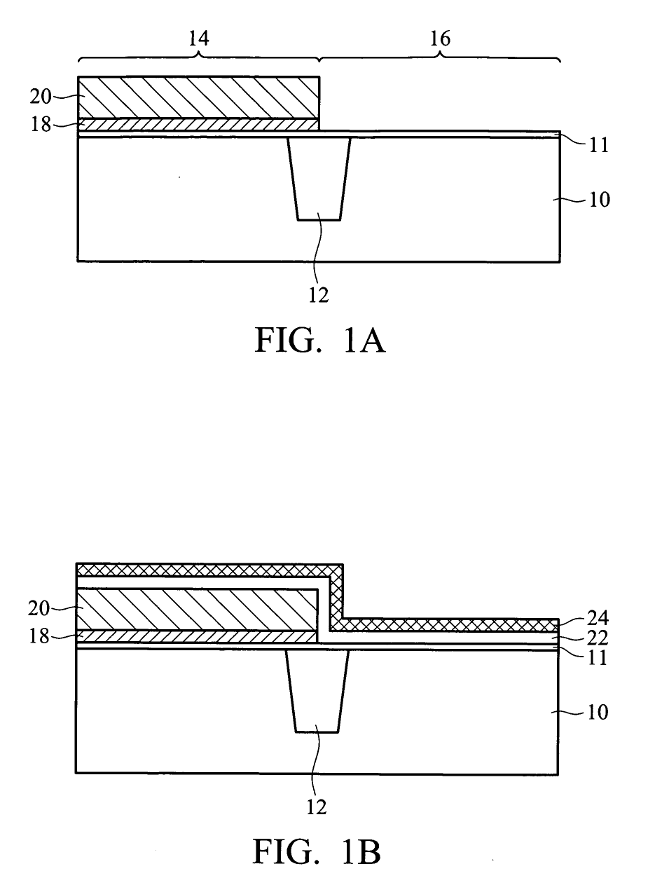

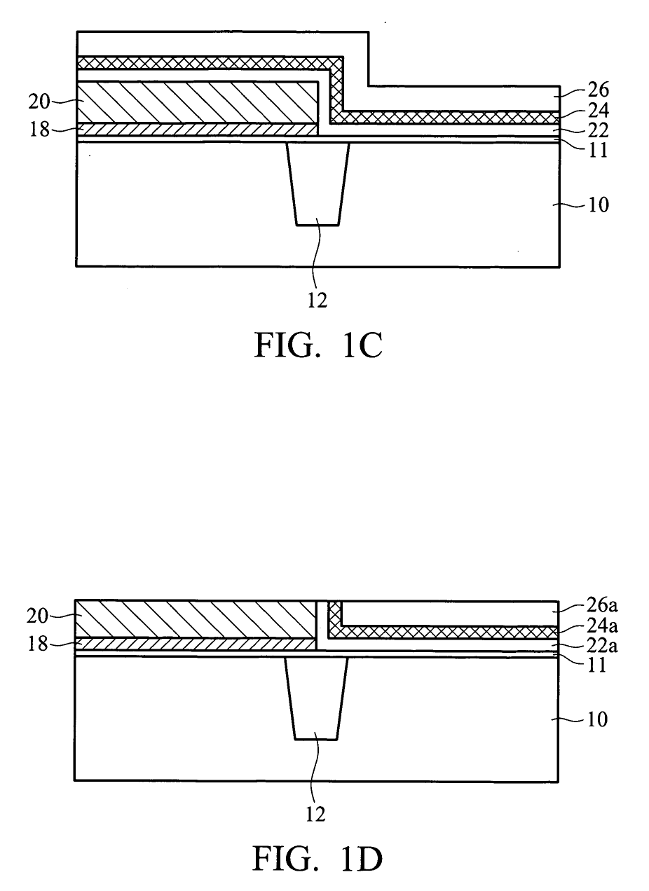

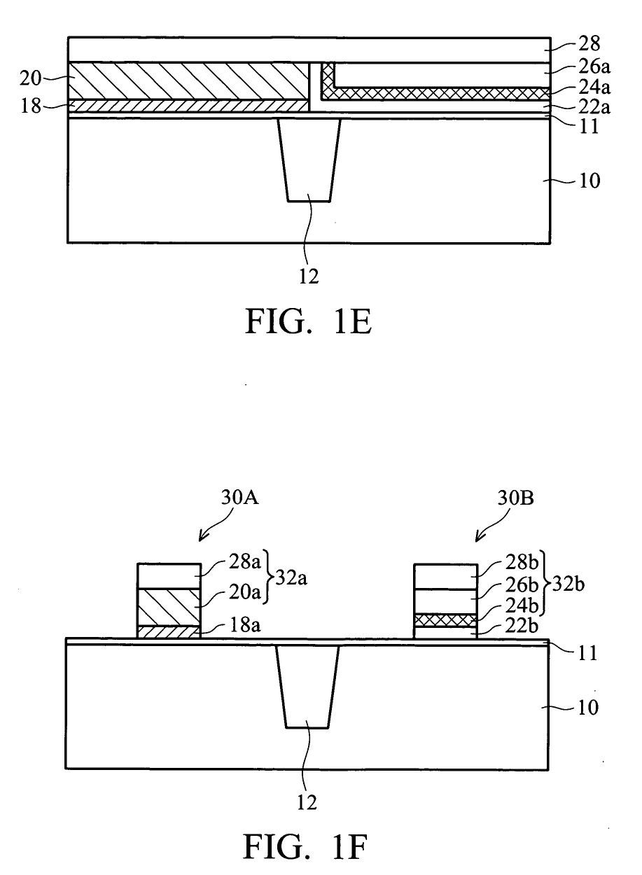

Herein, cross-sectional diagrams of FIG. 1A to FIG. 1F illustrate an exemplary embodiment of a method of forming different gate structures for a PMOS transistor and an NMOS transistor.

In FIG. 1A, initially a well/channel implants for PMOS and NMOS transistors and isolation steps for both transistor types are performed on a semiconductor substrate 10 in accordance with CMOS processing. The semiconductor substrate 10 comprises an isolation region 12 for electrically isolating a first device region 14 from a second device region 16. As will be described in the following disclosure in greater detail, the first device region 14 for forming a PMOS transistor refers to a PMOS device region 14, and the second device region 16 for forming an NMOS transistor refers to an NMOS device region 16. The NMOS and PMOS transistors may be fabricated on a P-well region and an N-well region, and may be fabricated directly onto or within the semiconductor substrate 10. The semiconductor substrate 10 may be formed of monocrystalline silicon, silicon germanium (SiGe), strained silicon on SiGe, gallium arsenic, silicon on insulator (SOI), silicon germanium on insulator (SGOI), germanium on insulator (GOI), GaAs, InP or the like. The substrate 10 may further comprise an interfacial layer 11 (e.g., a based oxide layer) to prevent the inter-diffusion of undesired elements between semiconductor substrate 10 and subsequently formed layers. The isolation region 12 may be formed as a shallow trench isolation structure (STI), an LOCOS type isolation structures, or a doped isolation region. In one embodiment as shown in FIG. 1A, the isolation region 12 is an STI structure formed by the traditional trench etching and deposition processes as known to one skilled in the art.

Referring to FIG. 1A, a first dielectric layer 18 and a first conductive layer 20 are successively deposited on the substrate 10, and then photolithography with masking technology and dry etch process are employed to remove the layers 18 and 20 from the NMOS device region 16. The remaining portion of the first dielectric layer 18 and the first conductive layer 20 on the PMOS device region 14 will be further patterned in subsequent processes to become at least part of a gate structure of a PMOS transistor, which will be described later.

The first dielectric layer 18 may be formed of silicon oxynitride (SiON) or high-k dielectric materials. As used throughout this disclosure, the term “high-k dielectric” refers to a dielectric material has a dielectric constant (k value) of greater than about 4, more preferably greater than about 8, and even more preferably greater than about 10. For example, a high-k dielectric material used for forming the first dielectric layer 18 may be HfₓO_{y}, HfₓSi_{y}O_{z}, HfSiON, HfSiON(Zr), ZrₓO_{y}, ZrₓSi_{y}O_{z}, HfTaTiOₓ, HfTaOₓ, HffiOₓ, other metal oxides (e.g., AlₓO_{y}, TiₓO_{y}, and TaₓO_{y}), or combinations thereof. Methods of forming the high-k dielectric material include commonly used technologies such as chemical vapor deposition (CVD), atomic layer deposition (ALD), plasma enhanced CVD (PECVD), and physical vapor deposition (PVD), etc. The thickness of the first dielectric layer 18 is between about 5 Angstroms and about 100 Angstroms.

The first conductive layer 20 may be formed of silicon-based materials or metal-based materials. Examples of silicon-based materials include polysilicon, doped polysilicon, amorphous silicon, single crystalline silicon, SiGe and the like. Metal-based materials include metal, metal nitrides and metal silicides, which preferably have P-channel metal characteristics and a work function suitable for a PMOS transistor. Impurities may be doped to change the work function of the metal-based materials. Examples of metal-based materials include W, WN, WCN, Ru, Pt, Ir, Mo, Mo₂N, MoON, Ta, TaN, TaC, TaCN, TaSiN, TiAlN, TiN, Cu, Al, IrSi, WSi, CoSi, MoSi₂, HfN, HfSi, NiSi, etc. Methods of forming the first conductive layer 20 include CVD, PVD, sputter, etc.

There are various material combinations of the first dielectric layer 18/first conductive layer 20 structure for forming the gate structure of the PMOS transistor. For example, the structure of the first dielectric layer 18/first conductive layer 20 is a SiON/polysilicon stack in one embodiment, a high-k dielectric/polysilicon stack in another embodiment, a high-k dielectric/metal stack in another embodiment, and a SiON/metal stack in the other embodiment.

In FIG. 1B, a second dielectric layer 22 and a second conductive layer 24 are successively deposited on both the PMOS device region 14 and the NMOS device region 16 of the substrate 10, covering the patterned structure including the first dielectric layer 18 and the first conductive layer 20. It is noted that a portion of the second dielectric layer 22 and the second conductive layer 24 will be removed from the PMOS device region 14 later, while a portion of the second dielectric layer 22 and the second conductive layer 24 will remain on the NMOS device region 16 and then be patterned in subsequent processes to become at least part of a gate structure of a NMOS transistor.

Although embodiments of the present invention illustrate a process of forming the first dielectric layer 18/first conductive layer 20 structure on the PMOS device region 14 first, the present invention provides value when using a process of forming the second dielectric layer 22/second conductive layer 24 structure on the NMOS device region 16 prior to the formation the first dielectric layer 18/first conductive layer 20 structure on the PMOS device region 14.

The second dielectric layer 22 may be formed of silicon oxynitride (SiON) or high-k dielectric materials. For example, a high-k dielectric material used for forming the second dielectric layer 22 may be HfₓO_{y}, HfₓSi_{y}O_{z}, HfSiON, HfSiON(Zr), ZrₓO_{y}, ZrₓSi_{y}O_{z}, HfTaTiOₓ, HfTaOₓ, HffiOₓ, other metal oxides (e.g., AlₓO_{y}, TiₓO_{y}, and TaₓO_{y}), or combinations thereof. Methods of forming the high-k dielectric material include commonly used technologies such as chemical vapor deposition (CVD), atomic layer deposition (ALD), plasma enhanced CVD (PECVD), and physical vapor deposition (PVD), etc. The thickness of the second dielectric layer. 22 is between about 5 Angstroms and about 100 Angstroms.

The second conductive layer 24 may be formed of silicon-based materials or metal-based materials. Examples of silicon-based materials include polysilicon, doped polysilicon, amorphous silicon, single crystalline silicon, SiGe and the like. Metal-based materials include metal, metal nitrides and metal silicides, which preferably have N-channel metal characteristics and a work function suitable for an NMOS transistor. Impurities may be doped to change the work function of the metal-based materials. Examples of metal-based materials include W, WN, WCN, Ru, Pt, Ir, Mo, Mo₂N, MoON, Ta, TaN, TaC, TaCN, TaSiN, TiAlN, TiN, Cu, Al, WSi, CoSi, MoSi₂, HfN, HfSi, NiSi, etc. Methods of forming the second conductive layer 24 include CVD, PVD, sputter, etc.

There are various material combinations of the second dielectric layer 22/second conductive layer 24 structure for forming the gate structure of the NMOS transistor. For example, the structure of the second dielectric layer 22/second conductive layer 24 is a SiON/polysilicon stack in one embodiment, a high-k dielectric/polysilicon stack in another embodiment, a high-k dielectric/metal stack in another embodiment, and a SiON/metal stack in the other embodiment.

For optimizing dual gate structures of a CMOS device, there are various combinations of the first stack (first dielectric layer 18/first conductive layer 20) on the PMOS device region 14 and the second stack (second dielectric layer 22/second conductive layer 24) on the NMOS device region 16. For example, in one embodiment, the first stack is a SiON/polysilicon stack and the second stack s a high-k dielectric/metal stack. In one embodiment, the first stack is a high-k dielectric/polysilicon stack and the second stack is a high-k dielectric/metal stack. In one embodiment, the first stack is a high-k dielectric/metal stack and the second stack is a SiON/polysilicon stack. In one embodiment, the first stack is a high-k dielectric/metal stack and the second stack is a SiON/metal stack. In one embodiment, the first stack is a high-k dielectric/metal stack and the second stack is a high-k dielectric/metal stack, while the two high-k dielectrics are formed of different materials with the same dielectric thickness. In one embodiment the first stack is a high-k dielectric/metal stack and the second stack is a high-k dielectric/metal stack, while the two high-k dielectrics are formed of the same material with different dielectric thicknesses.

In an optional step as shown in FIG. 1C, a protection layer 26 is deposited on the second conductive layer 24 for preventing the underlying metal-based material from oxidation. The protection layer 26 may be formed of a silicon-based material or a metal-based material. The protection layer 26 may be formed of the same material as the first conductive layer 20 or the second conductive layer 24. Examples of the protection layer 26 includes, but is not limited to, amorphous polysilicon, doped polysilicon, single crystalline silicon, metal, metal nitrides, metal silicides, and the like through methods of CVD, PVD, sputter, etc.

In FIG. 1D, advances in photolithography and masking technologies and dry etching processes are employed to expose the first conductive layer 20 which is substantially leveled off with the top of the protection layer 26 on the NMOS device region 16. In detailed, a patterned photoresist layer is provided on the NMOS device region 16, and then the uncovered portion of the protection layer 26, the second conductive layer 24 and the second dielectric layer 22 on the PMOS device region 14 are removed till the first conductive layer 20 on the PMOS device region 14 is exposed. The exposed top of the first conductive layer 20 is substantially leveled off with the remaining portion 26a of the protection layer 26 on the NMOS device region 16. The photoresist layer is then stripped, thus portions of the protection layer 26a, the second conductive layer 24a and the second dielectric layer 22a remain on the NMOS device region 16.

In anther optional step as shown in FIG. 1E, a capping layer 28 is deposited on both the PMOS device region 14 and the NMOS device region 16 to cover the first conductive layer 20 and the protection layer 26a for optimizing the height of the gate structure. The capping layer 28 may be formed of a silicon-based material, such as polysilicon, doped polysilicon, single crystalline silicon, amorphous silicon and the like through methods of CVD, PVD, sputter, etc. The thickness of the capping layer 28 is chosen specifically for the gate height requirements of the CMOS technology. For example, the capping layer 28 has a thickness from about 300 Angstroms to about 1500 Angstroms.

In FIG. 1F, using lithographic patterning and dry etching methods known in the art, the deposited layers 18, 20, 22a, 24a, 26a and 28 on the substrate 10 are patterned to become gate dielectric layers 18a and 22b and gate electrode layers 20a, 28a, 24b, 26b and 28b, completing a first gate structure 30A on the PMOS device region 14 and a second gate structure 30B on the NMOS device region 16 respectively. For the use of the PMOS transistor, the first gate structure 30A has a first gate dielectric layer 18a and a first gate conductor 32a including a first gate electrode layer 20aand a second gate electrode layer 28a. For the use of the NMOS transistor, the second gate structure 30B has a second gate dielectric layer 22b and a second gate conductor 32b including a first gate electrode layer 24b, a second gate electrode layer 26b and a third gate electrode layer 28b. P-channel and N-channel impurities may be further doped into the layers 28a and 28b for tuning suitable work functions for the gate structures 30A and 30B of the PMOS transistor and the NMOS transistors respectively. Processing continues to form source/drain extensions (if used) and source/drain regions in the substrate 10 by ion implantation, and dielectric spacers on the sidewalls of the gate structures 30A and 30B. The formation of these components is well known in the art and thus is not described.

Accordingly, fabrication of the gate structures 30A and 30B having substantially different gate conductors 32a and 32b is realizable using the processes of the present invention. The respective work functions of the gate conductors 32a and 32b are preferably tuned by using different combinations of gate electrode layers 20a, 28a, 24b, 26b and 28b. With such a design, the balanced work functions improve the performance of the CMOS device. Also, fabrication of gate structures 30A and 30B having substantially different gate dielectric properties (e.g., dielectric material, dielectric constant, and/or dielectric thickness) is realizable using the processes of the present invention. The gate dielectric layers 18a and 22b are formed of different dielectric materials with the same dielectric thickness. Alternatively, the gate dielectric layers 18a and 22b are formed of the same dielectric material with different dielectric thicknesses.

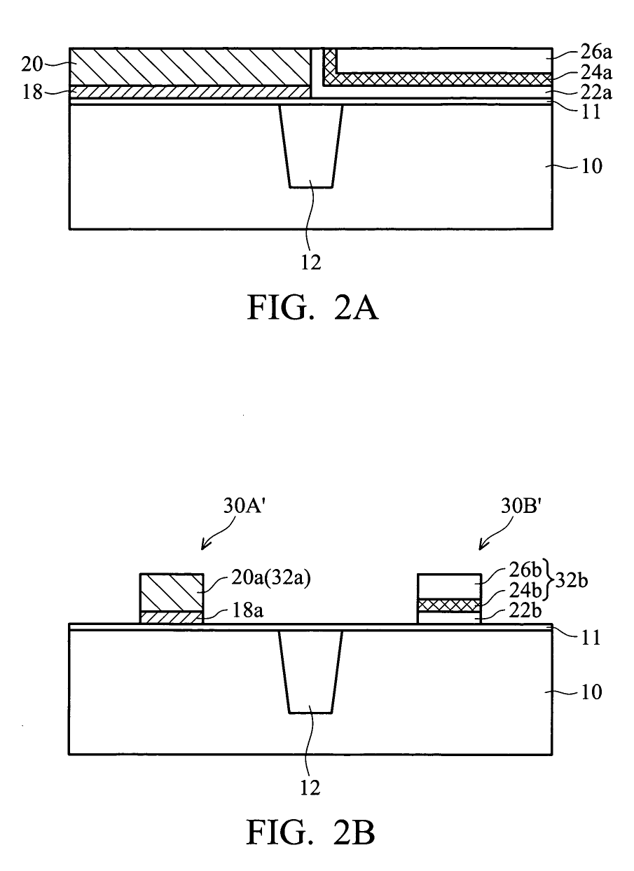

Cross-sectional diagrams of FIG. 2A to FIG. 2B illustrate an exemplary embodiment of a method of forming gate structures 30A′ and 30B′ without using the capping layer 28, and explanation of the same or similar portions to the description in the above-mentioned Figures is omitted herein. Compared with the process flow as depicted in FIG. 1A to 1F, FIG. 2A illustrates the same resulted structure as shown in FIG. 1D, and the formation of capping layer 28 as depicted in FIG. 1E is omitted in this embodiment. After using lithographic patterning and dry etching for patterning the deposited layers 18, 20, 22a, 24a and 26a, a first gate structure 30A′ has a first gate conductor 32a including one gate electrode layer 20a, and a second gate structure 30B′ has a second gate conductor 32b including two gate electrode layers 24b and 26b, as depicted in FIG. 2B.

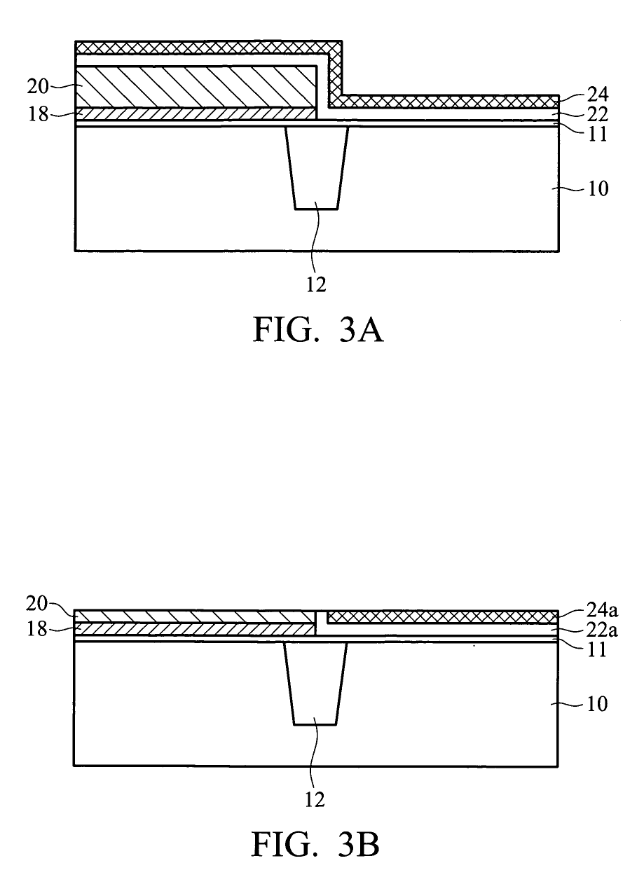

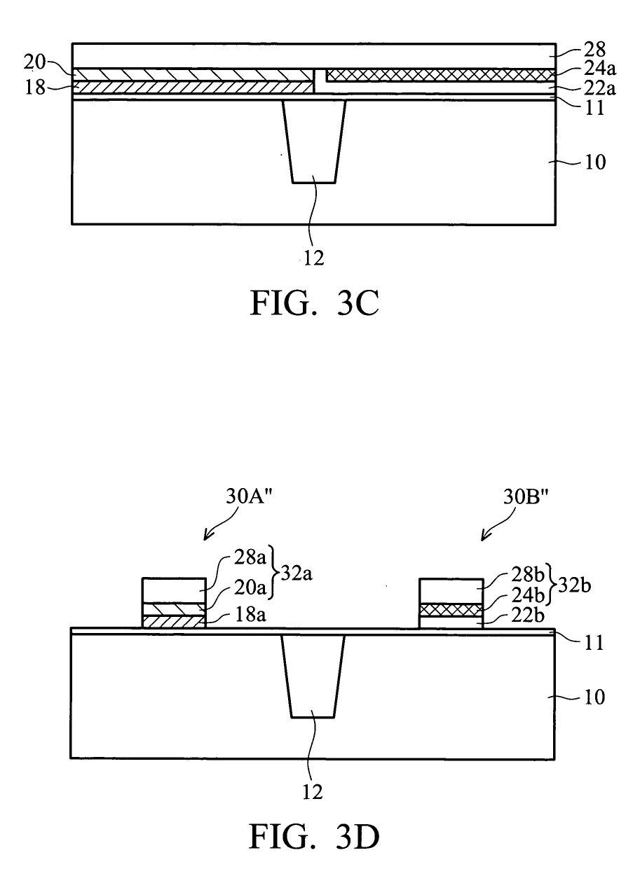

Cross-sectional diagrams of FIG. 3A to FIG. 3D illustrate an exemplary embodiment of a method of forming gate structures 30A” and 30B” without using the protection layer 26, and explanation of the same or similar portions to the description in the above-mentioned Figures is omitted herein. Compared with the process flow as depicted in FIG. 1A to 1F, FIG. 3A illustrates the same resulted structure as shown in FIG. 1B, and the formation of protection layer 26 as depicted in FIG. 1C is omitted in this embodiment. After using lithographic patterning and dry etching to remove the second conductive layer 24 and the second dielectric layer 24 from the PMOS device region 14, the first conductive layer 20 is exposed and leveled off with the top of the second conductive layer 24a remaining on the NMOS device region 16, as shown in FIG. 3B. Following the formation of capping layer 28 as shown in FIG. 3C, the deposited layers 18, 20, 22a, 24a and 28 are patterned to become a first gate structure 30A” has a first gate conductor 32a including two gate electrode layers 20aand 28a, and a second gate structure 30B” has a second gate conductor 32b including two gate electrode layers 24b and 28b, as depicted in FIG. 3D.

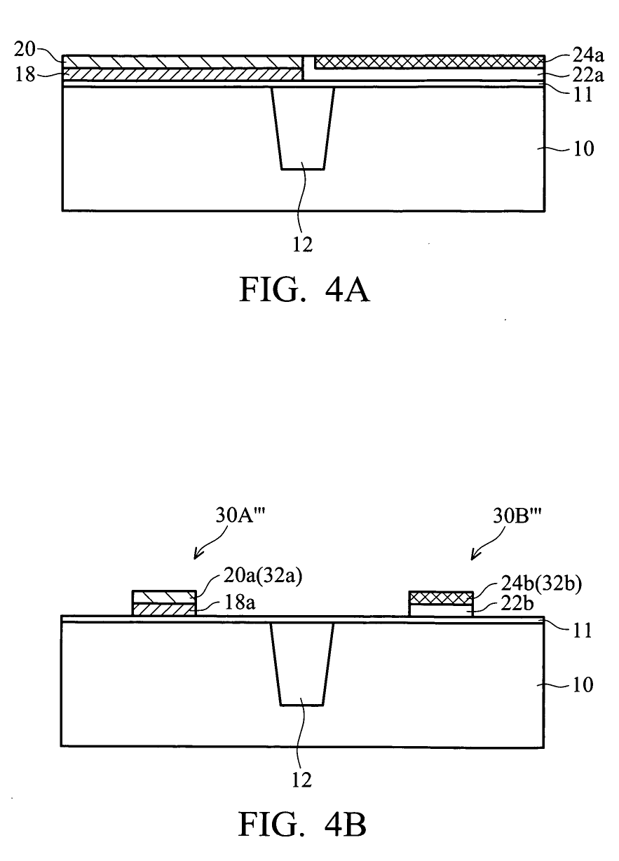

Cross-sectional diagrams of FIG. 4A to FIG. 4B illustrate an exemplary embodiment of a method of forming gate structures 30A′″ and 30B′″ without using the protection layer 26 and the capping layer 28, and explanation of the same or similar portions to the description in the above-mentioned Figures is omitted herein. Compared with the process flow as depicted in FIG. 1, FIG. 2 and FIG. 3, the formation of the protection layer 26 is omitted and FIG. 4A illustrates the same resulted structure as shown in FIG, 3B, and the formation of capping layer 28 also omitted in this embodiment. After using lithographic patterning and dry etching for patterning the deposited layers 18, 20, 22a and 24a, a first gate structure 30A′″ has a first gate conductor 32a including one gate electrode layer 20a, and the second gate structure 30B′″ has a second gate conductor 32b including one gate electrode layer 24 as depicted in FIG. 4B.

Although the present invention has been described in its preferred embodiments, it is not intended to limit the invention to the precise embodiments disclosed herein. Those skilled in this technology can still make various alterations and modifications without departing from the scope and spirit of this invention. Therefore, the scope of the present invention shall be defined and protected by the following claims and their equivalents.

What is claimed is:

1. A semiconductor device, comprising:
a semiconductor substrate having a p-channel metal oxide semiconductor (PMOS) device region and an n-channel metal oxide semiconductor (NMOS) device region;
a first gate structure overlying said PMOS device region, comprising a first gate dielectric layer overlying said semiconductor substrate, and a first gate conductor overlying said first gate dielectric layer; and
a second gate device region overlying said NMOS device region, comprising a second gate dielectric layer overlying said semiconductor substrate, and a second gate conductor overlying said first gate dielectric layer;
wherein, said first gate conductor comprises a silicon-based material layer, and said second gate conductor comprises a metal-based material layer.

2. The semiconductor device of claim 1, wherein said first gate dielectric layer and said second gate dielectric layer are formed of different dielectric materials selected from the group consisting of SiON, HfSiON and high-k dielectric materials.

3. The semiconductor device of claim 1, wherein said first gate dielectric layer and said second gate dielectric layer are formed of the same dielectric material with different dielectric thicknesses selected from the group consisting of SiON, HfSiON and high-k dielectric materials.

4. The semiconductor device of claim 1, wherein said silicon-based material layer of said first gate conductor is a polysilicon layer, and said metal-based materials layer of said second gate conductor is selected from the group consisting of TaC, TaN, TaSiN and HfN.

5. The semiconductor device of claim 1, further comprising a protection layer overlying said metal-based material layer of said second gate conductor, wherein said protection layer is selected from the group consisting of polysilicon, silicon-based materials and metal-based material.

6. The semiconductor device of claim 1, further comprising a capping layer overlying said metal-based material layer of said second gate conductor, wherein said capping layer is a polysilicon layer.

7. The semiconductor device of claim 1, further comprising:
a protection layer overlying said metal-based material layer of said second gate conductor, wherein said protection layer is selected from the group consisting of polysilicon, silicon-based materials and metal-based material; and
a capping layer overlying said protection layer, wherein said capping layer is a polysilicon layer.

8. The semiconductor device of claim 1, wherein said first gate structure and said second gate structure have the same height overlying said semiconductor substrate.

9. A semiconductor device, comprising:
a semiconductor substrate having a p-channel metal oxide semiconductor (PMOS) device region and an n-channel metal oxide semiconductor (NMOS) device region;
a first gate structure overlying said PMOS device region, comprising a first gate dielectric layer overlying said semiconductor substrate, and a first gate conductor overlying said first gate dielectric layer; and
a second gate device region overlying said NMOS device region, comprising a second gate dielectric layer overlying said semiconductor substrate, and a second gate conductor overlying said first gate dielectric layer;
wherein, said first gate conductor comprises a metal-based material layer, and said second gate conductor comprises a silicon-based material layer.

10. The semiconductor device of claim 9, wherein said first gate dielectric layer and said second gate dielectric layer are formed of different dielectric materials selected from the group consisting of SiON, HfSiON and high-k dielectric materials.

11. The semiconductor device of claim 9, wherein said first gate dielectric layer and said second gate dielectric layer are formed of the same dielectric material with different dielectric thicknesses selected from the group consisting of SiON, HfSiON and high-k dielectric materials.

12. The semiconductor device of claim 9, wherein said metal-based materials layer of said first gate conductor is selected from the group consisting of WN, WCN, Ru, Pt, Ir, Mo₂N and MoON, and said silicon-based material layer of said second gate conductor is a polysilicon layer.

13. The semiconductor device of claim 9, further comprising a protection layer overlying said silicon-based material layer of said second gate conductor, wherein said protection layer is selected from the group consisting of polysilicon, silicon-based materials and metal-based material.

14. The semiconductor device of claim 9, further comprising a capping layer overlying said silicon-based material layer of said second gate conductor, wherein said capping layer is a polysilicon layer.

15. The semiconductor device of claim 9, further comprising:
a protection layer overlying said silicon-based material layer of said second gate conductor, wherein said protection layer is selected from the group consisting of polysilicon, silicon-based materials and metal-based material; and
a capping layer overlying said protection layer, wherein said capping layer is a polysilicon layer.

16. The semiconductor device of claim 9, wherein said first gate structure and said second gate structure have the same height overlying said semiconductor substrate.

17. A semiconductor device, comprising:
a semiconductor substrate having a p-channel metal oxide semiconductor (PMOS) device region and an n-channel metal oxide semiconductor (NMOS) device region;
a first gate structure overlying said PMOS device region, comprising a first gate dielectric layer formed of SiON overlying said semiconductor substrate, and a first gate conductor formed of polysilicon overlying said first gate dielectric layer; and
a second gate device region overlying said NMOS device region, comprising a second gate dielectric layer formed of a high-k dielectric material overlying said semiconductor substrate, and a second gate conductor formed of a metal-based material overlying said first gate dielectric layer.

18. The semiconductor device of claim 17, wherein said high-k dielectric material of said second gate dielectric layer is selected from the group consisting of HfₓO_{y}, HfSiON, HfSiON(Zr), ZrₓO_{y}, HfTaTiOₓ, HfTaOₓ, HfTiOₓ and combinations thereof.

19. The semiconductor device of claim 17, wherein said metal-based material of said second gate conductor is selected from the group consisting of TaC, TaN, TaSiN and HfN.

20. The semiconductor device of claim 17, further comprising:
a protection layer overlying said metal-based material layer of said second gate conductor, wherein said protection layer is selected from the group consisting of polysilicon, silicon-based materials and metal-based material; and
a capping layer overlying said protection layer, wherein said capping layer is a polysilicon layer.
